(19) United States
(12) Patent Application Publication
(10) Pub. No.: US 2026/0331192 A1
(43) Pub. Date: Oct. 22, 2026

(54) MEMORY DEVICE AND OPERATING METHOD THEREOF

(71) Applicant: SK hynix Inc., Icheon-si Gyeonggi-do (KR)

(72) Inventors: Nam Cheol JEON, Icheon-si Gyeonggi-do (KR); Yong Gyu CHO, Icheon-si Gyeonggi-do (KR)

(73) Assignee: SK hynix Inc., Icheon-si Gyeonggi-do (KR)

(21) Appl. No.: 19/459,726

(22) Filed: Jan. 26, 2026

(30) Foreign Application Priority Data
Apr. 16, 2025 (KR) 10-2025-0049584

(51) Int. Cl. G11C 16/34; G11C 16/16

(52) U.S. Cl. CPC G11C 16/3472; G11C 16/16; G11C 16/3495

(57) ABSTRACT

A memory device includes a memory cell array including a plurality of memory blocks, a peripheral circuit configured to perform an erase operation on a selected memory block of the plurality of memory blocks, and control logic configured to control the peripheral circuit to perform a pre-program operation, a soft erase operation, and a main erase operation on the selected memory block during the erase operation.

### CROSS REFERENCE TO RELATED APPLICATION

The present application claims priority under 35 U.S.C. § 119(a) to Korean patent application number 10-2025-0049584 filed on Apr. 16, 2025, in the Korean Intellectual Property Office, the entire contents of which application is incorporated herein by reference.

### BACKGROUND

### 1. Technical Field

The present disclosure relates generally to electronic devices, and more particularly, to a memory device and a method of operating the memory device.

### 2. Related Art

Recently, the paradigm of the computer environment has shifted toward ubiquitous computing, where computer systems are available anytime, anywhere, leading to a surge in the use of portable electronic devices such as cell phones, digital cameras, and laptop computers. These portable electronic devices typically use memory systems or data storage devices. The data storage devices are used as either primary or secondary memory devices in the portable electronic devices.

A data storage device employing a memory device exhibits improved reliability and durability because the data storage device does not include a mechanical drive part and also provides fast data access and lower power consumption. Examples of memory systems with these advantages include Universal Serial Bus (USB) memory devices, memory cards with various interfaces, and solid state drives (SSD).

Memory devices are categorized as volatile memory devices or non-volatile memory devices.

Non-volatile memory devices have relatively slow write and read speeds, but retain stored data when the power is interrupted or without power. Therefore, non-volatile memory devices are used to store data that is retained regardless of whether power is supplied or not. Examples of non-volatile memory devices include Read Only Memory (ROM), Mask ROM (MROM), Programmable ROM (PROM), Erasable Programmable ROM (EPROM), Electrically Erasable Programmable ROM (EEPROM), Flash Memory, Phase Change Random Access Memory (PRAM), Magnetic RAM (MRAM), Resistive RAM (RRAM), Ferroelectric RAM (FRAM), and so forth. Flash memory is categorized as one of two types NOR or NAND.

A non-volatile memory device may perform an erase operation such that threshold voltages of selected memory cells may be lower than a set threshold voltage during an erase operation. A plurality of memory cells may be programmed among a plurality of program states as a result of a program operation, and a threshold voltage distribution for the plurality of programmed memory cells may be relatively wide. During an erase operation, the plurality of memory cells programmed to the plurality of program states may be erased simultaneously, and the plurality of erased memory cells may have a relatively wide threshold voltage distribution.

### SUMMARY

According to an embodiment, a memory device may include a memory cell array including a plurality of memory blocks, a peripheral circuit configured to perform an erase operation on a selected memory block of the plurality of memory blocks, and control logic configured to control the peripheral circuit to perform a pre-program operation, a soft erase operation, and a main erase operation on the selected memory block during the erase operation.

According to an embodiment, a method of operating a memory device may include performing a first pre-program operation, a soft erase operation, and a second pre-program operation sequentially on a selected memory block including programmed memory cells; performing a first main erase operation on the selected memory block after the second pre-program operation; and performing an erase verify operation after the first main erase operation.

According to an embodiment, a method of operating a memory device may include performing a first pre-program operation and a first main erase operation sequentially on a selected memory block including programmed memory cells, performing an erase verify operation after the first main erase operation, and terminating an erase operation when a result of the erase verify operation is determined as pass, and performing a second pre-program operation and a second main erase operation sequentially on the selected memory block when the result of the erase verify operation is determined as fail.

According to an embodiment, a method of operating a memory device may include sequentially performing a soft erase operation and a pre-program operation on a selected memory block including programmed memory cells, performing a first main erase operation after the pre-program operation, and performing an erase verify operation to determine an erase pass or an erase fail of the selected memory block.

### BRIEF DESCRIPTION OF THE DRAWINGS

FIG. 1 is a diagram illustrating a memory system according to an embodiment of the present disclosure;

FIG. 2 is a diagram illustrating a memory device according to an embodiment of the present disclosure;

FIG. 3 is a diagram illustrating a memory block according to an embodiment of the present disclosure;

FIG. 4 is a diagram illustrating an embodiment of a memory block configured in three dimensions according to an embodiment of the present disclosure;

FIG. 5 is a flowchart illustrating an erase operation of a memory device according to an embodiment of the present disclosure;

FIG. 6 is a threshold voltage distribution diagram for memory cells during an erase operation of a memory device according to an embodiment of the present disclosure;

FIG. 7 is a flowchart illustrating an erase operation of a memory device according to an embodiment of the present disclosure;

FIG. 8 is a flowchart illustrating an erase operation of a memory device according to an embodiment of the present disclosure;

FIG. 9 is a threshold voltage distribution diagram for memory cells during an erase operation of a memory device according to an embodiment of the present disclosure;

FIG. 10 is a diagram illustrating an embodiment of a memory system;

FIG. 11 is a diagram illustrating an embodiment of a memory system;

FIG. 12 is a diagram illustrating an embodiment of a memory system; and

FIG. 13 is a diagram illustrating an embodiment of a memory system.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “first” and “second” are used to distinguish between various elements and do not imply size, order, priority, quantity, or importance of the elements. For example, a first element may be referred to as a second element in one example, and the second element may be referred to as a first element in another example.

When one element is identified as “connected” or “coupled” to another element, the elements may be connected or coupled directly or through at least one intervening element between the elements. When two elements are identified as “directly connected” or “directly coupled,” one element is directly connected or directly coupled to the other element without an intervening element between the two elements.

Terms such as “top,” “bottom,” “on,” “side,” “lower,” “low,” “column,” “row,” “level,” and other terms implying relative spatial relationship or orientation are utilized only for the purpose of ease of description or reference to a drawing and are not otherwise limiting.

The present disclosure describes a memory device and a method of operating the memory device that can improve a threshold voltage distribution for memory cells during an erase operation of the memory device.

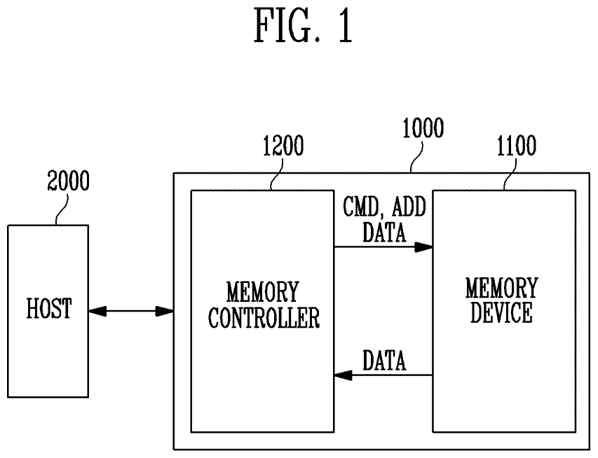

FIG. 1 is a diagram illustrating a memory system 1000 according to an embodiment of the present disclosure.

Referring to FIG. 1, a memory system 1000 may include a memory device 1100 in which data is stored, and a memory controller 1200 that controls the memory device 1100 in response to control by a host 2000.

The host 2000 may communicate with the memory system 1000 using an interface protocol such as Peripheral Component Interconnect Express (PCI-E), Advanced Technology Attachment (ATA), Serial ATA (SATA), Parallel ATA (PATA), or Serial Attached SCSI (SAS). Interface protocols between the host 2000 and the memory system 1000 are not limited to these examples and may be one of other interface protocols such as Universal Serial Bus (USB), Multi-Media Card (MMC), Enhanced Small Disk Interface (ESDI), or Integrated Drive Electronics (IDE).

The memory controller 1200 controls the overall operation of the memory system 1000 and may control exchange of data between the host 2000 and the memory device 1100. For example, the memory controller 1200 may control the memory device 1100 to program and read data in response to a request from the host 2000. During a program operation, the memory controller 1200 transfers to the memory device 1100 a command CMD corresponding to the program operation, an address ADD, and data DATA to be programmed. During a read operation, the memory controller 1200 may receive and temporarily store the data DATA read from the memory device 1100 and may transfer the temporarily stored data DATA to the host 2000.

The memory device 1100 may perform a program operation, a read operation, and an erase operation under control of the memory controller 1200. During an erase operation, the memory device 1100, according to an embodiment of the present disclosure, may perform a first pre-program operation, a soft erase operation, and a second pre-program operation prior to performing a main erase operation to form a narrow threshold voltage distribution for the memory cells. The memory device 1100, according to an embodiment of the present disclosure, may optionally leave out or skip the soft erase operation and precede to the pre-program operation before the main erase operation to improve the speed of the erase operation. The memory device 1100, according to an embodiment of the present disclosure, may perform the soft erase operation, the pre-program operation, and the main erase operation sequentially to form a narrow threshold voltage distribution for the memory cells.

The memory device 1100 may measure an internal temperature of the memory device 1100, may set a program voltage used during the pre-program operation based on the measured internal temperature, and may set a level of an erase voltage used during the soft erase operation during the erase operation. Also, The memory device 1100 may set a level of the program voltage or a voltage level of a bit line or a source line used during the pre-program operation and a level of the erase voltage used during the soft erase operation based on the program/erase (P/E) cycle count of a selected memory block during the erase operation. The program/erase cycle count refer to the cumulative number of program and erase operations performed on the selected memory block.

According to an embodiment, the memory device 1100 may include double data rate synchronous dynamic random access memory (DDR SDRAM), low power double data rate4 (LPDDR4) SDRAM, graphics double data rate (GDDR) SDRAM, low power DDR (LPDDR), Rambus dynamic random access memory (RDRAM), and/or flash memory.

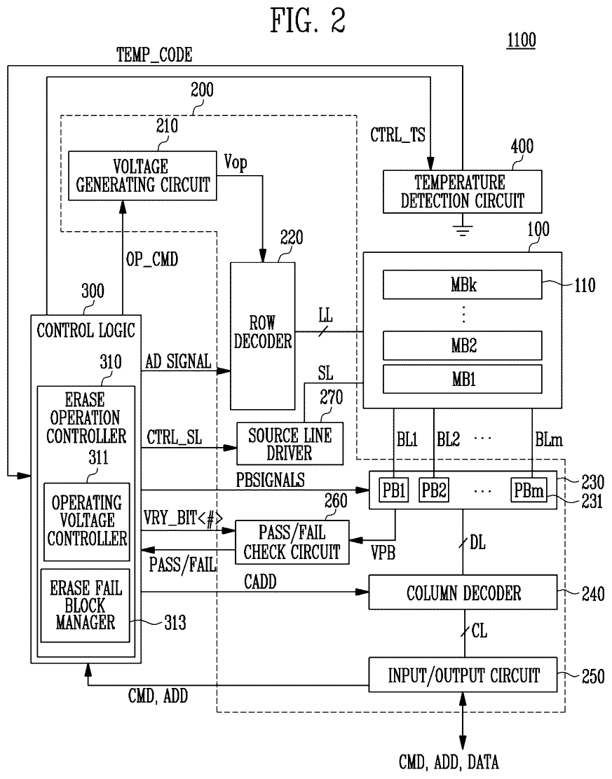

FIG. 2 is a diagram illustrating the memory device 1100 for example, as shown in FIG. 1.

Referring to FIG. 2, the memory device 1100 may include a memory cell array 100 in which data are stored. The memory device 1100 may include a peripheral circuit 200 configured to perform a program operation that stores data in the memory cell array 100, a read operation that outputs the stored data, and an erase operation that erases the stored data. The memory device 1100 may include control logic 300 that controls the peripheral circuit 200 under control of the memory controller 1200 in FIG. 1. The memory device 1100 may include a temperature detection circuit 400 that detects or measures the temperature of the memory device 1100. The control logic 300 may set operating voltages Vop used during a pre-program operation and a soft erase operation, both of which are performed as part of the erase operation, based on the temperature of the memory cell array 100 detected or measured by the temperature detection circuit 400 or the program/erase cycle count of the selected memory block.

The memory cell array 100 includes a plurality of memory blocks MB1 to MBk, where k is a positive integer. Local lines LL and bit lines BL1 to BLm, where m is a positive integer, may be coupled to each of the memory blocks MB1 to MBk. For example, the local lines LL may include a first select line, a second select line, and a plurality of word lines arranged between the first and second select lines. The local lines LL may include dummy lines arranged between the first select line and the word lines and between the second select line and the word lines. The first select line may be a source select line, and the second select line may be a drain select line. For example, the local lines LL may include word lines, drain select lines and source select lines, and source lines SL. For example, the local lines LL may include dummy lines. For example, the local lines LL may include pipe lines. The local lines LL may be coupled to each of the memory blocks MB1 to MBk, and the bit lines BL1 to BLm may be coupled in common to the memory blocks MB1 to MBk. The memory blocks MB1 to MBk may have a two-dimensional or a three-dimensional structure. For example, in memory blocks 110 having a two-dimensional structure, memory cells may be arranged parallel to a substrate. For example, in the memory blocks 110 having a three-dimensional structure, memory cells maybe stacked in a direction perpendicular to the substrate.

The peripheral circuit 200 may perform program operations, read operations, and erase operations of a selected memory block 110 under control of the control logic 300. For example, the peripheral circuit 200 may include a voltage generating circuit 210, a row decoder 220, a page buffer group 230, a column decoder 240, an input/output circuit 250, a pass/fail check circuit 260, and a source line driver 270.

The voltage generating circuit 210 may generate various operating voltages Vop used for program operations, read operations, and erase operations in response to an operating signal OP_CMD. In an embodiment, the voltage generating circuit 210 may generate the operating voltages Vop generated during a pre-program operation and the operating voltages Vop generated during a soft erase operation by adjusting the operating voltages Vop during the erase operation in response to control by an erase operation controller 310 included in the control logic 300. The voltage generating circuit 210 may include a pump.

The row decoder 220 may transfer the operating voltages Vop to the local lines LL coupled to the selected memory block 110 in response to row decoder control signals AD_SIGNAL. For example, the row decoder 220 may apply a pre-program operating voltage generated by the voltage generating circuit 210 to word lines of the selected memory block 110 in response to the row decoder control signals AD_SIGNAL during a pre-program operation during the erase operation. The row decoder 220 may apply an erase operation voltage generated by the voltage generating circuit 210 to the word lines of the selected memory block 110 in response to the row decoder control signals AD_SIGNAL during the soft erase operation and the main erase operation during the erase operation.

The page buffer group 230 may include a plurality of page buffers PB1 to PBm coupled to the bit lines BL1 to BLm. The page buffers PB1 to PBm may operate in response to page buffer control signals PBSIGNALS. For example, the page buffers PB1 to PBm may regulate a voltage level of the bit lines BL1 to BLm to a program enable voltage level, such as ground voltage, during a pre-program operation during an erase operation. Also, the page buffers PB1 to PBm may apply an erase voltage to the bit lines BL1 to BLm during a soft erase operation or a main erase operation.

The page buffers PB1 to PBm sense the voltage or current on the bit lines BL1 to BLm during an erase verify operation to verify whether the memory cells included in the selected memory block are erased to a normal erase state.

The column decoder 240 may transfer data between the input/output circuit 250 and the page buffer group 230 in response to the column address CADD. For example, the column decoder 240 may exchange data with the page buffers 231 via data lines DL or may exchange data with the input/output circuit 250 via column lines CL.

The input/output circuit 250 may transfer the command CMD and the address ADD received from the memory controller 1200 in FIG. 1 to the control logic 300 or may exchange the data DATA with the column decoder 240.

The pass/fail check circuit 260 may generate a reference current in response to an allowable bit VRY_BIT<#> during an erase verify operation and may output a pass signal PASS or a fail signal FAIL by comparing a reference voltage generated by the reference current with a sensing voltage VPB received from the page buffer group 230. The sensing voltage VPB may be controlled based on the number of memory cells determined to pass during the erase verify operation.

The source line driver 270 is coupled via the source line SL to the memory cells included in the memory cell array 100, and may control the voltage applied to the source line SL. For example, the source line driver 270 may receive a source line control signal CTRL_SL from the control logic 300 and may apply an erase voltage to the source line SL based on the source line control signal CTRL_SL during a soft erase operation or a main erase operation during an erase operation.

The control logic 300 may control the peripheral circuit 200 by outputting the operating signal OP_CMD, the row decoder control signals AD_SIGNAL, the page buffer control signals PBSIGNALS, and the allowable bit VRY_BIT<#> in response to the command CMD and the address ADD. The control logic 300 may control the temperature detection circuit 400 by outputting a temperature detection control signal CTRL_TS when the command CMD corresponding to the erase operation is received.

The control logic 300 may include the erase operation controller 310. The erase operation controller 310 may control the peripheral circuit 200 to perform an erase operation on the selected memory block during the erase operation. The erase operation controller 310 may control the peripheral circuit 200 to sequentially perform a first pre-program operation, a soft erase operation, a second pre-program operation, and a main erase operation during the erase operation. The erase operation controller 310 may control the peripheral circuit 200 to perform the pre-program operation and the main erase operation sequentially during the erase operation and to perform the pre-program operation and the main erase operation again when a result of the main erase operation is determined to fail. The erase operation controller 310 may control the peripheral circuit 200 to sequentially perform the soft erase operation, the pre-program operation, and the main erase operation during the erase operation.

The erase operation controller 310 includes an operating voltage controller 311 and an erase-fail block manager 313.

The operating voltage controller 311 may set a level of a program voltage used in the pre-program operation and a level of an erase voltage used in the soft erase operation based on a temperature code TEMP_CODE corresponding to the temperature detected by the temperature detection circuit 400 or the Program/Erase cycle count of the selected memory block in the erase operation.

The erase-fail block manager 313 may manage erase failures identified in the plurality of memory blocks MB1 to MBk included in the memory cell array 100. The erase-fail block manager 313 may manage a memory block that is ultimately determined as erase-failed during an erase operation to update them as erase-fail block.

The temperature detection circuit 400 may measure the temperature of the memory device 1100 in response to the temperature detection control signal CTRL_TS output from the control logic 300 and may convert the measured temperature to a digital code to generate the temperature code TEMP_CODE. The generated temperature code TEMP_CODE may be output to the erase operation controller 310 of the control logic 300. The temperature detection circuit 400 may be disposed in an area adjacent to the memory cells. For example, the temperature detection circuit 400 may be disposed on the sides or top and bottom of the memory cell array 100 or inside the memory cell array 100.

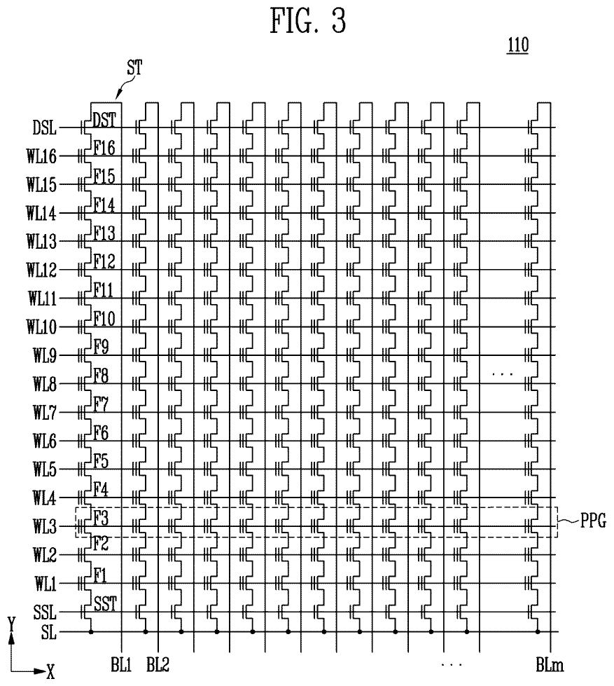

FIG. 3 is a diagram illustrating the memory block 110, for example, as shown in FIG. 2.

Referring to FIG. 3, in the memory block 110, a plurality of word lines arranged parallel may be coupled between a first select line and a second select line. The first select line may be a source select line SSL and the second select line may be a drain select line DSL. For example, the memory block 110 may include a plurality of strings ST coupled between the bit lines BL1 to BLm and the source line SL. The bit lines BL1 to BLm may be individually coupled to the strings ST, and the source line SL may be coupled in common to the strings ST. Because the strings ST may be configured substantially similarly, the string ST coupled to the first bit line BL1 is described as an example.

The string ST may include a source select transistor SST, a plurality of memory cells F1 to F16, and a drain select transistor DST coupled in series between the source line SL and the first bit line BL1. One string ST may include at least one source select transistor SST, at least one drain select transistor DST, and additional memory cells than the number of memory cells F1 to F16 shown in FIG. 3.

A source of the source select transistor SST may be coupled to the source line SL, and a drain of the drain select transistor DST may be coupled to the first bit line BL1. The memory cells F1 to F16 may be coupled in series between the source select transistor SST and the drain select transistor DST. Gates of the source select transistors SST in different strings ST may be coupled to the source select line SSL, gates of the drain select transistors DST may be coupled to the drain select line DSL, and gates of the memory cells F1 to F16 may be coupled to a plurality of word lines WL1 to WL16. Among the memory cells included in different strings ST, a group of memory cells coupled to the same word line may be referred to as a page PPG. Thus, the memory block 110 may include as many pages PPG as the number of word lines WL1 to WL16.

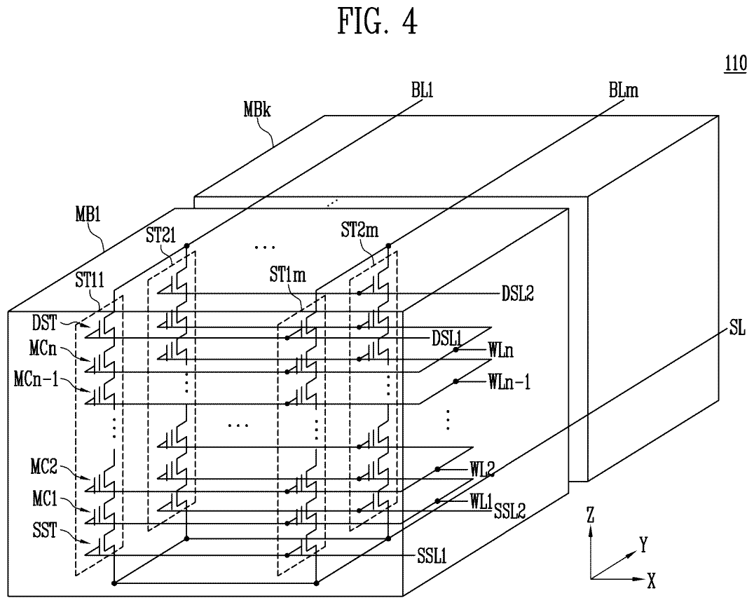

FIG. 4 is a diagram illustrating an embodiment of a memory block configured in three dimensions.

Referring to FIG. 4, the memory cell array 100 may include a plurality of memory blocks MB1 to MBk. The memory blocks 110 may include a plurality of strings ST11 to ST1m and ST21 to ST2m. For example, each of the plurality of strings ST11 to ST1m and ST21 to ST2m may be formed in an ‘I’ shape or a ‘U’ shape. Within the first memory block MB1, m strings may be arranged in a row direction, an X direction. In FIG. 4, two strings are shown arranged in a column direction, a Y direction, for simplicity of illustration, and three or more strings may be arranged in the column direction, the Y direction.

Each of the plurality of strings ST11 to ST1m and ST21 to ST2m may include at least one source select transistor SST, first memory cell MC1 to nth memory cell MCn and at least one drain select transistor DST.

The source select transistor SST of each string may be coupled between the source line SL and the memory cells MC1 to MCn. Source select transistors of strings arranged in the same row may be coupled to the same source select line. Source select transistors of the strings ST11 to ST1m arranged in a first row may be coupled to a first source select line SSL1 . Source select transistors of the strings ST21 to ST2m arranged in a second row may be coupled to a second source select line SSL2. In an embodiment, the source select transistors of the strings ST11 to ST1m and ST21 to ST2m may be coupled in common to one source select line.

The memory cells MC1 to MCn of each string may be coupled in series between the source select transistor SST and the drain select transistor DST. Gates of the memory cells MC1 to MCn may be coupled to word lines WL1 to WLn, respectively.

In an embodiment, at least one of the memory cells MC1 to MCn may function as a dummy memory cell. When a dummy memory cell is included, the voltage or current of the corresponding string may be stably controlled. Accordingly, the reliability of the data stored in the memory block 110 may be improved.

The drain select transistors DST of each string may be coupled between the bit line and the memory cells MC1 to MCn. The drain select transistors DST of the strings arranged in the row direction may be coupled to a drain select line extending in the row direction. The drain select transistors DST of the strings ST11 to ST1m in the first row may be coupled to a first drain select line DSL1. The drain select transistors DST of the strings ST21 to ST2m in the second row may be coupled to a second drain select line DSL2.

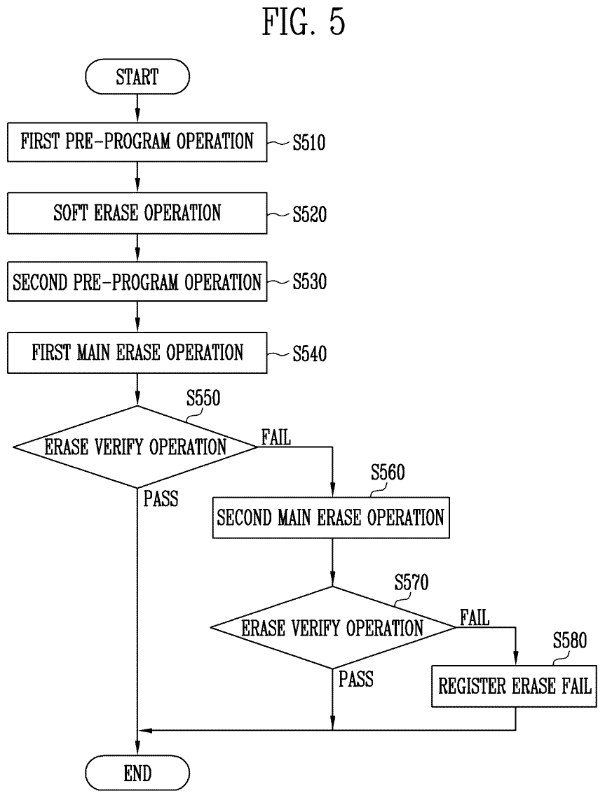

FIG. 5 is a flowchart illustrating an erase operation of a memory device according to an embodiment of the present disclosure. The processes of the flowchart may be performed in a different order and may include fewer or additional processes than described and shown in FIG. 5.

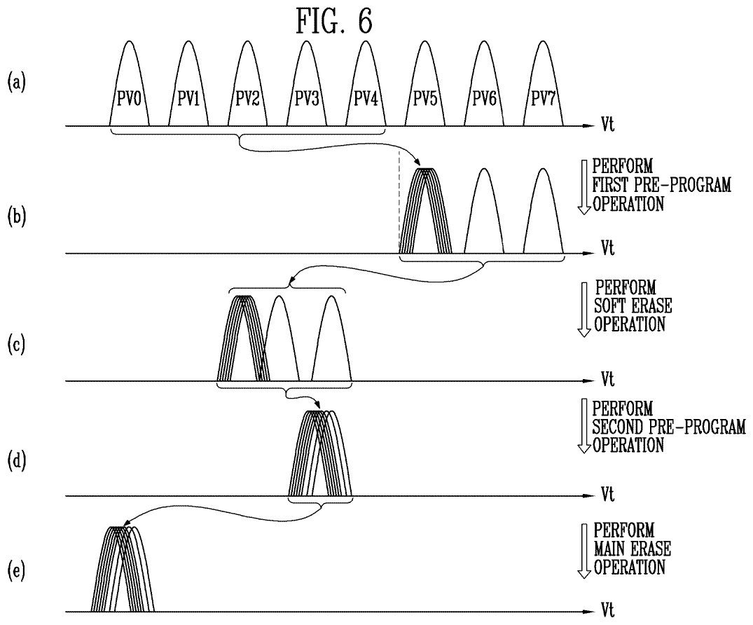

FIG. 6 is a threshold voltage distribution diagram of memory cells during an erase operation of a memory device according to an embodiment of the present disclosure.

Referring to FIG. 2 to FIG. 6, an erase operation of a memory device according to an embodiment of the present disclosure is described.

At step S510, the memory device 1100 may perform a first pre-program operation on the memory block MB1 when the memory device 110 receives the command CMD instructing performance of an erase operation on the selected memory block(e.g., MB1).

The temperature detection circuit 400 may measure the temperature of the memory device 1100 in response to the temperature detection control signal CTRL_TS output from the control logic 300, may convert the measured temperature to a digital code, and may generate and outputs the temperature code TEMP_CODE.

The erase operation controller 310 of the control logic 300 may set a level of a pre-program voltage or a voltage level of a bit line or a source line used during a first pre-program operation based on the temperature code TEMP_CODE or the program/erase cycle count of the memory block MB1.

The peripheral circuit 200 may perform a first pre-program operation on the memory block MB1 under control of the erase operation controller 310. For example, the voltage generating circuit 210 may generate the pre-program voltage in response to the received operating signal OP_CMD, and the row decoder 220 may apply the pre-program voltage to a selected word line of the word lines WL1 to WL16 of the memory block MB1. The plurality of page buffers PB1 to PBm coupled to the bit lines BL1 to BLm may apply a program enable voltage, such as ground voltage, to the bit lines BL1 to BLm.

The first pre-program operation may be performed by sequentially applying a plurality of gradually increasing pre-program voltages. The first pre-program operation may be performed by sequentially or simultaneously selecting a plurality of pages included in the memory block MB1.

Referring to row (a) of FIG. 6, a plurality of memory cells included in the memory block MB1 may have threshold voltages corresponding to an erase state PV0 and a plurality of program states PV1 to PV7. When the first pre-program operation is performed, the threshold voltages of the memory cells corresponding to the erase state PV0 and some of the program states, such as PV1 to PV4, corresponding to a relatively low threshold voltage distribution as shown in row (b) may rise. As a result, the threshold voltage distribution for all memory cells may be narrower after performing the pre-program operation than before performing the first pre-program operation.

At step S520, after the first pre-program operation is completed, a soft erase operation may be performed on the memory block MB1.

The erase operation controller 310 of the control logic 300 may set an erase voltage, a gate-induced drain leakage GIDL operation voltage, and an erase operation voltage used during the soft erase operation based on the temperature code TEMP_CODE or the program/erase cycle count of the memory block MB1. The erase voltage may be applied to the source line SL or the bit lines BL1 to BLm of the memory block MB1, the GIDL operation voltage may be applied to the source select line SSL or the drain select line DSL of the memory block MB1, and the erase operation voltage may be applied to the word lines WL1 to WL16 of the memory block MB1.

The peripheral circuit 200 may perform the soft erase operation on the memory block MB1 under control of the erase operation controller 310. For example, the voltage generating circuit 210 may generate the GIDL operation voltage and the erase operation voltage in response to the received operating signal OP_CMD, and the row decoder 220 may apply the GIDL operation voltage to the source select line SSL or the drain select line DSL of the memory block MB1 and may apply the erase operation voltage to the word lines WL1 to WL16. The plurality of page buffers PB1 to PBm or the source line driver 270 may apply the erase voltage to the bit lines BL1 to BLm or the source line SL to perform the soft erase operation.

Referring to row (b) and row (c) of FIG. 6, the threshold voltage distribution for the plurality of memory cells may be generally lowered as the soft erase operation is performed.

At step S530, after the soft erase operation is completed, a second pre-program operation for the memory block MB1 is performed. The second pre-program operation may be performed similarly to the first pre-program operation.

The erase operation controller 310 of the control logic 300 may set a level of a pre-program voltage or a voltage level of a bit line or a source line used during the second pre-program operation based on the temperature code TEMP_CODE or the program/erase cycle count in the memory block MB1.

The peripheral circuit 200 may perform the second pre-program operation on the memory block MB1 under control of the erase operation controller 310. For example, the voltage generating circuit 210 may generate the pre-program voltage in response to the received operating signal OP_CMD, and the row decoder 220 may apply the pre-program voltage to a selected word line of the word lines WL1 to WL16 of the memory block MB1. The plurality of page buffers PB1 to PBm coupled to the bit lines BL1 to BLm may apply a program enable voltage, such as ground voltage, to the bit lines BL1 to BLm.

The second pre-program operation may be performed by sequentially applying a plurality of gradually increasing pre-program voltages. The second pre-program operation may be performed by sequentially or simultaneously selecting a plurality of pages included in the memory block MB1.

Referring to row (c) and row (d) of FIG. 6, the threshold voltage distribution for the plurality of memory cells may be further narrowed by the second pre-program operation.

At step S540 after the second pre-program operation is completed, a first main erase operation may be performed on the memory block MB1.

The erase operation controller 310 of the control logic 300 may control the peripheral circuit 200 to perform the first main erase operation.

The peripheral circuit 200 may perform a main erase operation for the memory block MB1 under control of the erase operation controller 310. For example, the voltage generating circuit 210 may generate the GIDL operation voltage and the erase operation voltage in response to the received operating signal OP_CMD, and the row decoder 220 may apply the GIDL operation voltage to the source select line SSL or the drain select line DSL of the memory block MB1 and may apply the erase operation voltage to the word lines WL1 to WL16. The plurality of page buffers PB1 to PBm or the source line driver 270 may apply the erase voltage to the bit lines BL1 to BLm or the source line SL to perform the first main erase operation.

Referring to row (d) and row (e) of FIG. 6, the threshold voltage distribution for the plurality of memory cells may be generally lowered or shifted as a result of performing the first main erase operation.

At step S550, an erase verify operation may be performed on the memory block MB1.

The voltage generating circuit 210 may generate an erase verify voltage in response to the received operating signal OP_CMD, and the row decoder 220 may apply the erase verify voltage to the word lines WL1 to WL16 of the memory block MB1. The page buffers PB1 to PBm may sense the voltage or current on the bit lines BL1 to BLm to verify whether the memory cells included in the memory block MB1 are erased to a normal erase state.

The pass/fail check circuit 260 may output the pass signal PASS or the fail signal FAIL by comparing the sensing voltage VPB received from the page buffer group 230 and a reference voltage generated from a reference current. The erase operation controller 310 may determine pass or fail for the first main erase operation based on the pass signal PASS or the fail signal FAIL.

When the first main erase operation is determined to pass, the erase operation may be terminated.

When the result of the erase verify operation of step S550 is determined as fail, the main erase operation and the erase verify operation may be performed again. For example, at step S560, a second main erase operation may be performed.

The erase operation controller 310 of the control logic 300 may control the peripheral circuit 200 to perform the second main erase operation.

The peripheral circuit 200 may perform a main erase operation for the memory block MB1 under the control of the erase operation controller 310. For example, the voltage generating circuit 210 may generate the GIDL operation voltage and the erase operation voltage in response to the received operating signal OP_CMD, and the row decoder 220 may apply the GIDL operation voltage to the source select line SSL or the drain select line DSL of the memory block MB1 and may apply the erase operation voltage to the word lines WL1 to WL16. The plurality of page buffers PB1 to PBm or the source line driver 270 may apply the erase voltage to the bit lines BL1 to BLm or the source line SL to perform the second main erase operation.

At step S570, an erase verify operation may be performed on memory block MB1.

The voltage generating circuit 210 may generate an erase verify voltage in response to the received operating signal OP_CMD, and the row decoder 220 applies the erase verify voltage to the word lines WL1 to WL16 of the memory block MB1. The page buffers PB1 to PBm may sense the voltage or current on the bit lines BL1 to BLm to verify whether the memory cells included in the memory block MB1 are erased to a normal erase state.

The pass/fail check circuit 260 may output the pass signal PASS or the fail signal FAIL by comparing the sensing voltage VPB received from the page buffer group 230 and a reference voltage generated from a reference current. The erase operation controller 310 may determine pass or fail for the second main erase operation based on the pass signal PASS or the fail signal FAIL.

When the second main erase operation is determined to pass, the erase operation may be terminated.

When the result of the erase verify operation of step S570 is determined as fail, the memory block MB1 may be registered as an erase-fail block at step S580. For example, the erase-fail block manager 313 may manage the memory block MB1 by updating or identifying the memory block MB1 as an erase-fail block for which the second main erase operation is determined as fail.

In an embodiment of the present disclosure, when the first main erase operation is determined as fail, the second main erase operation and the erase verify operation may be performed again, and the memory block may be updated as an erase-fail block according to the result of the second main erase operation. When the second main erase operation is determined as fail, an additional main erase operation and an additional erase verify operation may be repeated a predetermined number of times.

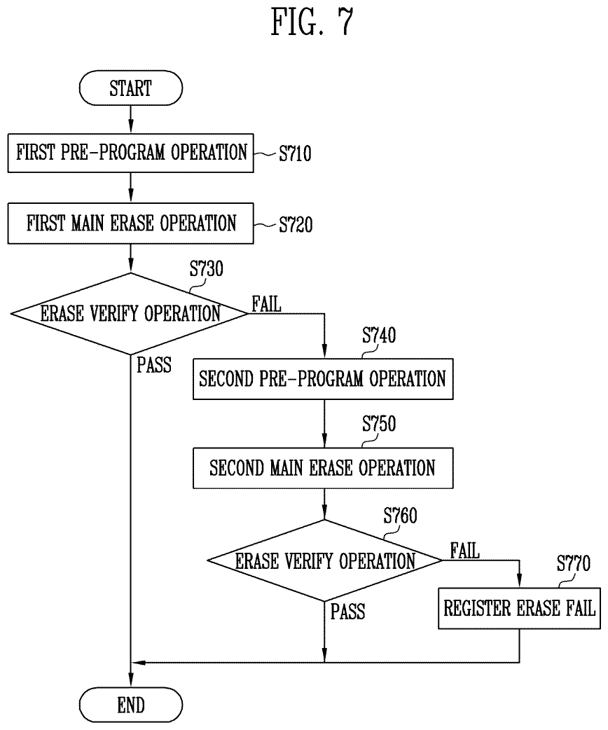

FIG. 7 is a flowchart illustrating an erase operation of a memory device according to an embodiment of the present disclosure. The processes of the flowchart may be performed in a different order and may include fewer or additional processes than described and shown in FIG. 7.

Referring to FIG. 2 to FIG. 4 and FIG. 7, an erase operation of a memory device according to an embodiment of the present disclosure is described.

At step S710, the memory device 1100 may perform a first pre-program operation on the memory block MB1 when the memory device 1100 receives the command CMD instructing an erase operation on the selected memory block (e.g., MB1).

The temperature detection circuit 400 may measure the temperature of the memory device 1100 in response to the temperature detection control signal CTRL_TS output from the control logic 300, may convert the measured temperature to a digital code, and may generate and outputs the temperature code TEMP_CODE.

The erase operation controller 310 of the control logic 300 may set a level of a pre-program voltage or a voltage level of a bit line or a source line used during the first pre-program operation based on the temperature code TEMP_CODE or the program/erase cycle count of the memory block MB1.

The peripheral circuit 200 may perform the first pre-program operation on the memory block MB1 under control of the erase operation controller 310. For example, the voltage generating circuit 210 may generate the pre-program voltage in response to the received operating signal OP_CMD, and the row decoder 220 may apply the pre-program voltage to a selected word line of the word lines WL1 to WL16 of the memory block MB1. The plurality of page buffers PB1 to PBm coupled to the bit lines BL1 BLm may apply a program enable voltage, such as ground voltage, to the bit lines BL1 to BLm.

The first pre-program operation may be performed by sequentially applying a plurality of gradually increasing pre-program voltages. The first pre-program operation may be performed by sequentially or simultaneously selecting a plurality of pages included in the memory block MB1.

At step S720, after the first pre-program operation is completed, a first main erase operation may be performed on the memory block MB1.

The erase operation controller 310 of the control logic 300 may control the peripheral circuit 200 to perform the first main erase operation.

The peripheral circuit 200 may perform a main erase operation for the memory block MB1 under control of the erase operation controller 310. For example, the voltage generating circuit 210 may generate a GIDL operation voltage and an erase operation voltage in response to the received operating signal OP_CMD, and the row decoder 220 may apply the GIDL operation voltage to the source select line SSL or the drain select line DSL of the memory block MB1 and may apply the erase operation voltage to the word lines WL1 to WL16. The plurality of page buffers PB1 to PBm or the source line driver 270 may applie an erase voltage to the bit lines BL1 to BLm or the source line SL to perform the first main erase operation.

At step S730, an erase verify operation may be performed on memory block MB1.

The voltage generating circuit 210 may generate an erase verify voltage in response to the received operating signal OP_CMD, and the row decoder 220 may apply the erase verify voltage to the word lines WL1 to WL16 of the memory block MB1. The page buffers PB1 to PBm may sense the voltage or current on the bit lines BL1 to BLm to verify whether the memory cells included in the memory block MB1 are erased to a normal erase state.

The pass/fail check circuit 260 may output the pass signal PASS or the fail signal FAIL by comparing the sensing voltage VPB received from the page buffer group 230 and a reference voltage generated from a reference current. The erase operation controller 310 may determine pass or fail for the first main erase operation based on the pass signal PASS or the fail signal FAIL.

When the first main erase operation is determined to pass, the erase operation may be terminated.

When the result of erase verify operation of step S730 is determined as fail, the pre-program operation and the main erase operation may be performed again. For example, at step S740, a second pre-program operation may be performed. The second pre-program operation may be performed similarly to the first pre-program operation.

The erase operation controller 310 of the control logic 300 may set a level of a pre-program voltage or a voltage level of a bit line or a source line used during the second pre-program operation based on the temperature code TEMP_CODE or the program/erase cycle count of the memory block MB1.

The peripheral circuit 200 may perform the second pre-program operation on the memory block MB1 under control of the erase operation controller 310. For example, the voltage generating circuit 210 may generate the pre-program voltage in response to the received operating signal OP_CMD, and the row decoder 220 may apply the pre-program voltage to a selected word line of the word lines WL1 to WL16 of the memory block MB1. The plurality of page buffers PB1 to PBm coupled to the bit lines BL1 to BLm may apply a program enable voltage, such as ground voltage, to the bit lines BL1 to BLm.

The second pre-program operation may be performed by sequentially applying a plurality of gradually increasing pre-program voltages. The second pre-program operation may be performed by sequentially or simultaneously selecting a plurality of pages included in the memory block MB1.

At step S750, after the second pre-program operation is completed, a second main erase operation may be performed on the memory block MB1.

The erase operation controller 310 of the control logic 300 may control the peripheral circuit 200 to perform the second main erase operation.

The peripheral circuit 200 may perform a main erase operation for the memory block MB1 under control of the erase operation controller 310. For example, the voltage generating circuit 210 may generate the GIDL operation voltage and the erase operation voltage in response to the received operating signal OP_CMD, and the row decoder 220 may apply the GIDL operation voltage to the source select line SSL or the drain select line DSL of the memory block MB1 and may apply the erase operation voltage to the word lines WL1 to WL16. The plurality of page buffers PB1 to PBm or the source line driver 270 may apply the erase voltage to the bit lines BL1 to BLm or the source line SL to perform the second main erase operation.

At step S760, an erase verify operation may be performed on memory block MB1.

The voltage generating circuit 210 may generate an erase verify voltage in response to the received operating signal OP_CMD, and the row decoder 220 may apply the erase verify voltage to the word lines WL1 to WL16 of the memory block MB1. The page buffers PB1 to PBm may sense the voltage or current on the bit lines BL1 to BLm to verify whether the memory cells included in the memory block MB1 are erased to a normal erase state.

The pass/fail check circuit 260 may output the pass signal PASS or the fail signal FAIL by comparing the sensing voltage VPB received from the page buffer group 230 and a reference voltage generated from a reference current. The erase operation controller 310 may determine pass or fail for the second main erase operation based on the pass signal PASS or the fail signal FAIL.

When the result of second main erase operation is determined to pass, the erase operation may be terminated.

When the result of the erase verify operation of step S760 is determined as to be a fail, the memory block MB1 may be registered as an erase-fail block at step S770. For example, the erase-fail block manager 313 may manage the memory block MB1 by updating or identifying the memory block MB1 for which the second main erase operation is determined to fail as an erase-fail block.

In an embodiment of the present disclosure, the pre-program operation may be performed immediately before the main erase operation. For example, a first pre-program operation may be performed prior to a first main erase operation, and a second pre-program operation may be performed prior to a second main erase operation.

In an embodiment of the present disclosure, the memory block may be updated or identified as an erase-fail block based on the result of the erase verify operation after the second main erase operation. When the result of second main erase operation is determined as fail, an additional main erase operation and an additional erase verify operation may be repeated a predetermined number of times.

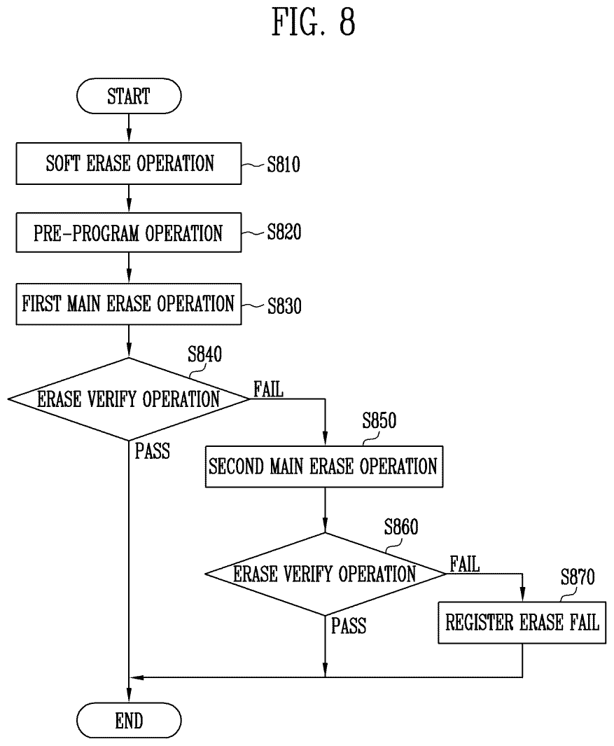

FIG. 8 is a flowchart illustrating an erase operation of a memory device according to an embodiment of the present disclosure. The processes of the flowchart may be performed in a different order and may include fewer or additional processes than described and shown in FIG. 8.

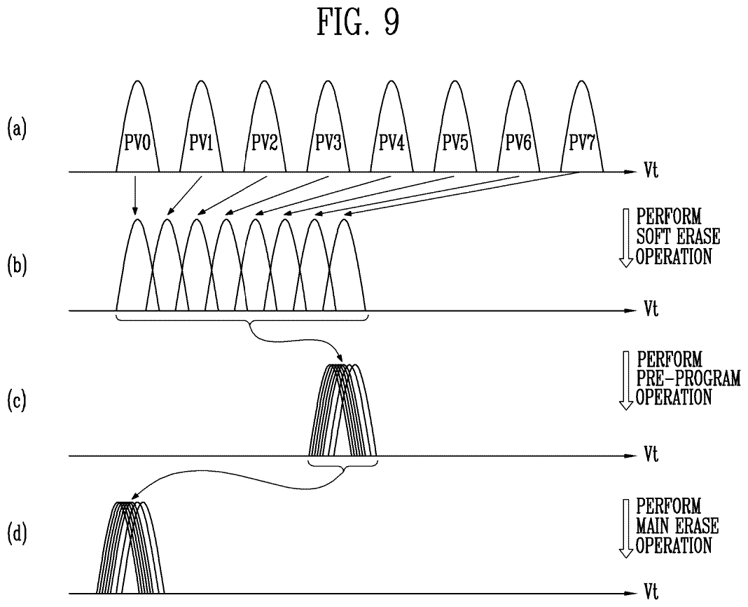

FIG. 9 is a threshold voltage distribution diagram for the memory cells during an erase operation of a memory device according to an embodiment of the present disclosure.

Referring to FIG. 2 to FIG. 4, FIG. 8, and FIG. 9, the erase operation of the memory device according to an embodiment of the present disclosure is described.

At step S810, the memory device 1100 may perform a soft erase operation on the memory block MB1 when the memory device 1100 receives the command CMD instructing performance of an erase operation on the selected memory block(e.g., MB1).

The erase operation controller 310 of the control logic 300 may set an erase voltage, a GIDL operation voltage, and an erase operation voltage used during the soft erase operation based on the temperature code TEMP_CODE or the program/erase cycle count of the memory block MB1. The erase voltage may be applied to the source line SL or the bit lines BL1 to BLm of the memory block MB1, the GIDL operation voltage may be applied to the source select line SSL or the drain select line DSL of the memory block MB1, and the erase operation voltage may be applied to the word lines WL1 to WL16 of the memory block MB1.

The peripheral circuit 200 may perform the soft erase operation on the memory block MB1 under control of the erase operation controller 310. For example, the voltage generating circuit 210 may generate the GIDL operation voltage and the erase operation voltage in response to the received operating signal OP_CMD, and the row decoder 220 may applie the GIDL operation voltage to the source select line SSL or the drain select line DSL of the memory block MB1 and may apply the erase operation voltage to the word lines WL1 to WL16. The plurality of page buffers PB1 to PBm or the source line driver 270 may apply the erase voltage to the bit lines BL1 to BLm or the source line SL to perform the soft erase operation.

Referring to row (a) of FIG. 9, the plurality of memory cells included in the memory block MB1 may have threshold voltages corresponding to the erase state PV0 and the plurality of program states PV1 to PV7. Subsequently, when the soft erase operation is performed, threshold voltages of the plurality of program states PV1 to PV7 may be lowered, as shown in row (b). Accordingly, the threshold voltage distribution for the memory cells may be narrower after performing the soft erase operation than before the soft erase operation is performed.

At step S820, a pre-program operation may be performed on the memory block MB1.

The temperature detection circuit 400 may measure the temperature of the memory device 1100 in response to the temperature detection control signal CTRL_TS output from the control logic 300, may convert the measured temperature to a digital code, and may generate and outputs the temperature code TEMP_CODE.

The erase operation controller 310 of the control logic 300 may set a level of a pre-program voltage or a voltage level of a bit line or a source line used during the pre-program operation based on the temperature code TEMP_CODE or the program/erase cycle count of the memory block MB1.

The peripheral circuit 200 may perform the pre-program operation on the memory block MB1 under control of the erase operation controller 310. For example, the voltage generating circuit 210 may generate the pre-program voltage in response to the received operating signal OP_CMD, and the row decoder 220 may apply the pre-program voltage to a selected word line of the word lines WL1 to WL16 of the memory block MB1. The plurality of page buffers PB1 to PBm coupled to the bit lines BL1 to BLm may apply a program enable voltage, such as ground voltage, to the bit lines BL1 to BLm.

The pre-program operation may be performed by sequentially applying a plurality of gradually increasing pre-program voltages. The pre-program operation may be performed by sequentially or simultaneously selecting a plurality of pages included in the memory block MB1.

Referring to row (c) of FIG. 9, the threshold voltage distribution for the memory cells of the memory block MB1 may further narrow as the pre-program operation is performed. For example, the threshold voltages of the memory cells corresponding to the relatively low erase state and the plurality of program states may increase, and the overall threshold voltage distribution for the memory cells may be narrower.

At step S830, after the pre-program operation is completed, a first main erase operation may be performed on the memory block MB1.

The erase operation controller 310 of the control logic 300 may control the peripheral circuit 200 to perform the first main erase operation.

The peripheral circuit 200 may perform a main erase operation for the memory block MB1 under control of the erase operation controller 310. For example, the voltage generating circuit 210 may generate the GIDL operation voltage and the erase operation voltage in response to the received operating signal OP_CMD, and the row decoder 220 may apply the GIDL operation voltage to the source select line SSL or the drain select line DSL of the memory block MB1 and may apply the erase operation voltage to the word lines WL1 to WL16. The plurality of page buffers PB1 to PBm or the source line driver 270 may apply the erase voltage to the bit lines BL1 to BLm or the source line SL to perform the first main erase operation.

Referring to row (d) of FIG. 9, the threshold voltage distribution for the plurality of memory cells may be generally lowered or shifted as the first main erase operation is performed.

At step S840, an erase verify operation may be performed on the memory block MB1.

The voltage generating circuit 210 may generate an erase verify voltage in response to the received operating signal OP_CMD, and the row decoder 220 may apply the erase verify voltage to the word lines WL1 to WL16 of the memory block MB1. The page buffers PB1 to PBm may sense the voltage or current on the bit lines BL1 to BLm to verify whether the memory cells included in the memory block MB1 are erased to a normal erase state.

The pass/fail check circuit 260 may output the pass signal PASS or the fail signal FAIL by comparing the sensing voltage VPB received from the page buffer group 230 and a reference voltage generated from a reference current. The erase operation controller 310 may determine pass or fail for the first main erase operation based on the pass signal PASS or the fail signal FAIL.

When the first main erase operation is determined to pass, the erase operation may be terminated.

When the erase verify operation of step S840 is determined as fail, the main erase operation and the erase verify operation may be performed again. For example, at step S850, a second main erase operation may be performed.

The erase operation controller 310 of the control logic 300 may control the peripheral circuit 200 to perform the second main erase operation.

The peripheral circuit 200 may perform a main erase operation for the memory block MB1 under the control of the erase operation controller 310. For example, the voltage generating circuit 210 may generate the GIDL operation voltage and the erase operation voltage in response to the received operating signal OP_CMD, and the row decoder 220 may apply the GIDL operation voltage to the source select line SSL or the drain select line DSL of the memory block MB1 and may apply the erase operation voltage to the word lines WL1 to WL16. The plurality of page buffers PB1 to PBm or the source line driver 270 may apply the erase voltage to the bit lines BL1 to BLm or the source line SL to perform the second main erase operation.

At step S860, an erase verify operation may be performed on memory block MB1.

The voltage generating circuit 210 may generate an erase verify voltage in response to the received operating signal OP_CMD, and the row decoder 220 may apply the erase verify voltage to the word lines WL1 to WL16 of the memory block MB1. The page buffers PB1 to PBm may sense the voltage or current on the bit lines BL1 to BLm to verify whether the memory cells included in the memory block MB1 are erased to a normal erase state.

The pass/fail check circuit 260 may output the pass signal PASS or the fail signal FAIL by comparing the sensing voltage VPB received from the page buffer group 230 and a reference voltage generated from a reference current. The erase operation controller 310 may determine pass or fail for the second main erase operation based on the pass signal PASS or the fail signal FAIL.

When the second main erase operation is determined to pass, the erase operation may be terminated.

When the result of the erase verify operation of step S860 is determined as fail, the memory block MB1 may be registered S870 as an erase-fail block. For example, the erase-fail block manager 313 may manage the memory block MB1 by updating or identifying the memory block MB1 for which the second main erase operation is determined to fail as an erase-fail block.

In an embodiment of the present disclosure, when the result of the first main erase operation is determined as fail, the second main erase operation and the erase verify operation may be performed again, and the memory block may be updated as an erase-fail block according to the result of the second main erase operation. When the result of the second main erase operation is determined as fail, an additional main erase operation and an additional erase verify operation may be repeated a predetermined number of times.

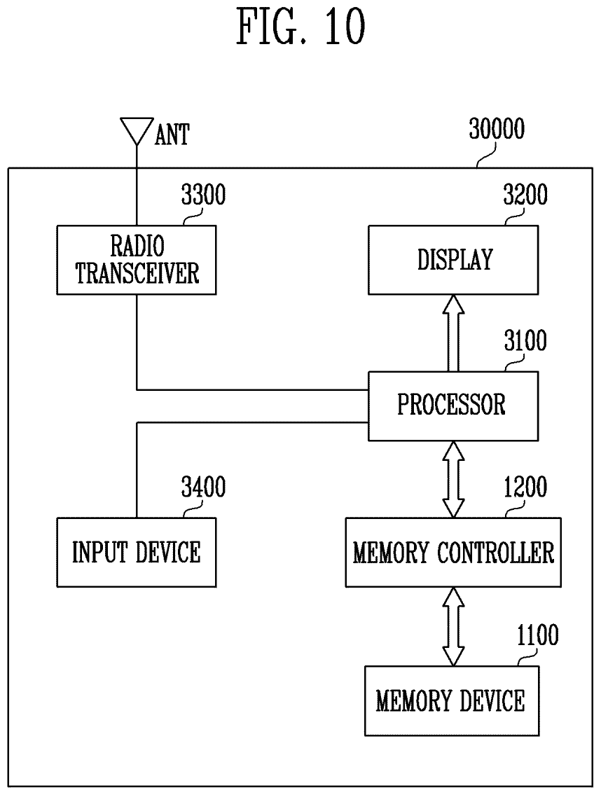

FIG. 10 is a diagram illustrating an embodiment of the memory system.

Referring to FIG. 10, a memory system 30000 may be a cellular phone, a smart phone, a tablet computer, a personal computer (PC), a personal digital assistant (PDA), a wireless communication device, and so forth. The memory system 30000 may include the memory device 1100 and the memory controller 1200 that control operation of the memory device 1100. The memory controller 1200 may control data access operation of the memory device 1100, for example, a program operation, an erase operation, and a read operation in response to control by a processor 3100.

The memory controller 1200 may control data programmed into the memory device 1100 that may be output via a display 3200. For example, the memory controller 1200 controls the memory device 1100 to perform an erase operation as described with respect to FIG. 1 through FIG. 9.

A radio transceiver 3300 may exchange a radio signal through an antenna ANT. For example, the radio transceiver 3300 may convert the radio signal received through the antenna ANT into a signal processed by the processor 3100. Therefore, the processor 3100 may process the signal output from the radio transceiver 3300 and may transfer the processed signal to the memory controller 1200 or the display 3200. The memory controller 1200 may program the signal processed by the processor 3100 into the memory device 1100. The radio transceiver 3300 may convert signals output from the processor 3100 into radio signals and outputs the radio signals to an external device through the antenna ANT. A control signal that controls operation of the processor 3100 or data to be processed by the processor 3100 may be input by an input device 3400. The input device 3400 may include a pointing device, such as a touch pad, a computer mouse, a keypad, or a keyboard. The processor 3100 may control operation of the display 3200 such that data output from the memory controller 1200, data output from the radio transceiver 3300, and data output from an input device 3400 may be output via the display 3200.

According to an embodiment, the memory controller 1200 that controls operation of the memory device 1100 may be included in the processor 3100 or may be a separate integrated circuit chip from the processor 3100. The memory controller 1200 may be implemented based on the memory controller 1200 described and shown in FIG. 1, and the memory device 1100 may be implemented based on the memory device 1100 described and shown in FIG. 2.

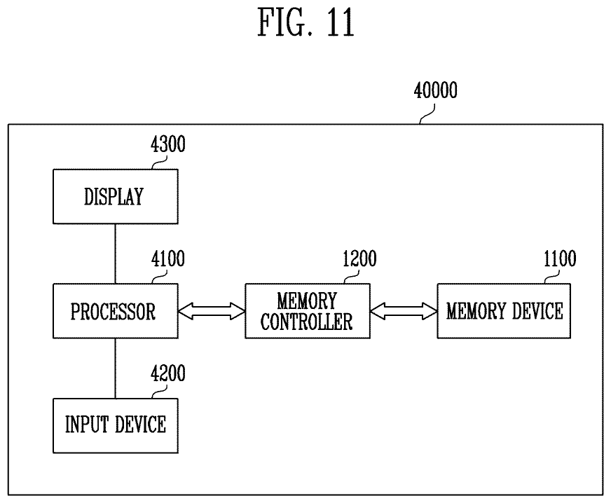

FIG. 11 is a diagram illustrating an embodiment of the memory system.

Referring to FIG. 11, a memory system 40000 may be a personal computer (PC), a tablet computer, a net-book, an e-reader, a personal digital assistant (PDA), a portable multimedia player (PMP), an MP3 player, an MP4 player, and so forth.

The memory system 40000 may include the memory device 1100 and the memory controller 1200 that control data processing operation of the memory device 1100. For example, the memory controller 1200 controls the memory device 1100 to perform an erase operation as described with respect to FIG. 1 through FIG. 9.

A processor 4100 may output data stored in the memory device 1100 via a display 4300 according to data input through an input device 4200. Examples of the input device 4200 may include a pointing device such as a touch pad, a computer mouse, a keypad, or a keyboard.

The processor 4100 may control various operations of the memory system 40000 and may control operation of the memory controller 1200. According to an embodiment, the memory controller 1200 that controls the operations of the memory device 1100 may be included in the processor 4100 or may be a separate integrated circuit chip from the processor 4100. The memory controller 1200 may be implemented based on the memory controller 1200 described and shown in FIG. 1, and the memory device 1100 may be implemented based on the memory device 1100 described and shown in FIG. 2.

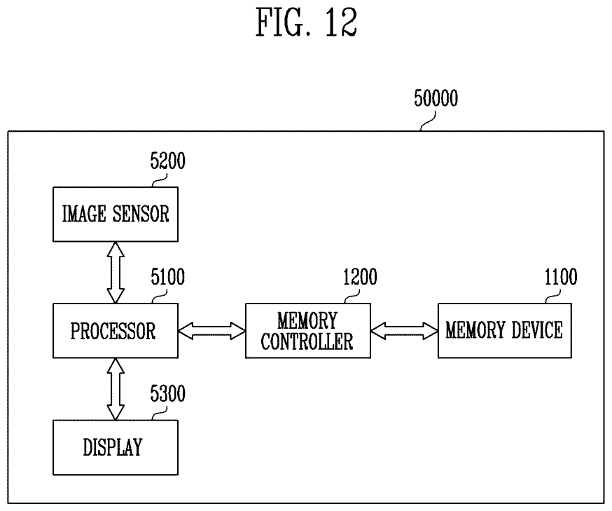

FIG. 12 is a diagram illustrating an embodiment of the memory system.

Referring to FIG. 12, a memory system 50000 may be embodied into an image processor, for example, a digital camera, a cellular phone including a digital camera, a smart phone including a digital camera, or a tablet PC including a digital camera.

The memory system 50000 may include the memory device 1100 and the memory controller 1200 that controls data processing operation of the memory device 1100, for example, a program operation, an erase operation, and a read operation. For example, the memory controller 1200 controls the memory device 1100 to perform an erase operation as described with respect to FIG. 1 through FIG. 9.

An image sensor 5200 of the memory system 50000 may convert an optical image into digital signals, and the digital signals may be transferred to a processor 5100 or the memory controller 1200. In response to control by the processor 5100, the digital signals may be output via a display 5300 or stored in the memory device 1100 using the memory controller 1200. The data stored in the memory device 1100 may be output via the display 5300 according to control by the processor 5100 or the memory controller 1200.

According to an embodiment, the memory controller 1200 that controls operation of the memory device 1100 may be included in the processor 5100 or may be a separate integrated circuit chip from the processor 5100. The memory controller 1200 may be implemented based on the memory controller 1200 described and shown in FIG. 1, and the memory device 1100 may be implemented based on the memory device 1100 described and shown in FIG. 2.

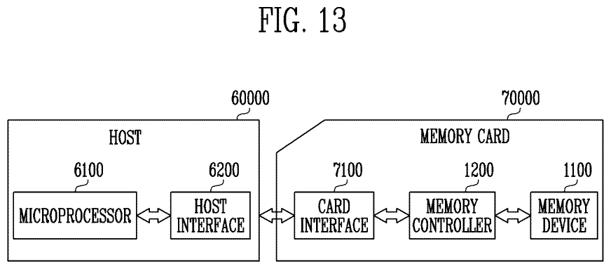

FIG. 13 is a diagram illustrating an embodiment of the memory system.

Referring to FIG. 13, a memory system 70000 may be a memory card or a smart card. The memory system 70000 may include the memory device 1100, the memory controller 1200, and a card interface 7100.

The memory controller 1200 may control data exchange between the memory device 1100 and the card interface 7100. According to an embodiment, the card interface 7100 may be, for example, a secure digital (SD) card interface or a multi-media card (MMC) interface. The memory controller 1200 may be implemented based on the memory controller 1200 described and shown in FIG. 1, and the memory device 1100 may be implemented based on the memory device 1100 described and shown in FIG. 2. For example, the memory controller 1200 controls the memory device 1100 to perform an erase operation as described with respect to FIG. 1 through FIG. 9.

The card interface 7100 may provide an interface for data exchange between a host 60000 and the memory controller 1200 according to a protocol of the host 60000. The card interface 7100 may support a Universal Serial Bus (USB) protocol and an InterChip (IC)-USB protocol. The card interface 7100 may refer to hardware capable of supporting a protocol used by the host 6000, software installed in the hardware, and/or a signal transmission method.

When the memory system 70000 is connected to a host interface 6200 of the host 60000 such as a personal computer (PC), a tablet computer, a digital camera, a digital audio player, a cellular phone, a console video game hardware, or a digital set-top box, the host interface 6200 may perform data communication with the memory device 1100 through the card interface 7100 and the memory controller 1200 in response to control by a microprocessor 6100.

According to an embodiment of the present disclosure, during an erase operation of a memory device, after a pre-program operation and a soft erase operation are performed to resulting in a narrow threshold voltage distribution for memory cells, a main erase operation is performed, thereby improving a threshold voltage distribution for erased memory cells.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A memory device comprising:
a memory cell array including a plurality of memory blocks;
a peripheral circuit configured to perform an erase operation on a selected memory block of the plurality of memory blocks; and
control logic configured to control the peripheral circuit to perform a pre-program operation, a soft erase operation, and a main erase operation on the selected memory block during the erase operation.

2. The memory device of claim 1, wherein the control logic is configured to control the peripheral circuit to sequentially perform the pre-program operation, the soft erase operation, and the main erase operation.

3. The memory device of claim 2, wherein the control logic is configured to control the peripheral circuit to perform an additional pre-program operation after the soft erase operation.

4. The memory device of claim 1, wherein the control logic is configured to control the peripheral circuit to perform an erase verify operation after the main erase operation and to control the peripheral circuit to perform an additional main erase operation and an additional erase verify operation when a result of the erase verify operation is determined as fail.

5. The memory device of claim 4, wherein the control logic is configured to manage the selected memory block as an erase-fail block when a result of the additional erase verify operation is determined as fail.

6. The memory device of claim 1, wherein the control logic is configured to control the peripheral circuit to sequentially perform the soft erase operation, the pre-program operation, and the main erase operation.

7. The memory device of claim 1, further comprising a temperature detection circuit configured to measure an internal temperature during the erase operation, to generate a temperature code based in the measured internal temperature, and to output the temperature code to the control logic.

8. The memory device of claim 7, wherein the control logic is configured to set operating voltages used during the pre-program operation and the soft erase operation based on the temperature code or a program/erase cycle count of the selected memory block.

9. The memory device of claim 8, wherein the control logic comprises:
an operating voltage controller configured to set the operating voltages based on the temperature code or the program/erase cycle count of the selected memory block; and
an erase-fail block manager configured to register and manage the selected memory block as an erase-fail block when the selected memory block is determined as an erase fail.

10. A method of operating a memory device, the method comprising:
performing a first pre-program operation, a soft erase operation, and a second pre-program operation sequentially on a selected memory block including programmed memory cells;
performing a first main erase operation on the selected memory block after the second pre-program operation; and
performing an erase verify operation after the first main erase operation.

11. The method of claim 10, further comprising, before performing the first pre-program operation:
measuring an internal temperature; and
setting operating voltages for the first pre-program operation, the soft erase operation, and the second pre-program operation based on a measured internal temperature or a program/erase cycle count of the selected memory block.

12. The method of claim 10, further comprising, after the erase verify operation, performing a second main erase operation and a second erase verify operation when a result of the erase verify operation is determined as fail.

13. The method of claim 12, wherein when a result of the second erase verify operation is determined as fail, the selected memory block is registered as an erase-fail block and an erase operation is terminated.

14. A method of operating a memory device, the method comprising:
performing a first pre-program operation and a first main erase operation sequentially on a selected memory block including programmed memory cells;
performing an erase verify operation after the first main erase operation; and
terminating an erase operation when a result of the erase verify operation is determined as pass, and performing a second pre-program operation and a second main erase operation sequentially on the selected memory block when the result of the erase verify operation is determined as fail.

15. The method of claim 14, further comprising, before performing the first pre-program operation:
measuring an internal temperature; and
setting operating voltages for the first pre-program operation based on the measured internal temperature or a program/erase cycle count of the selected memory block.

16. The method of claim 14, further comprising:
performing a second erase verify operation after the second main erase operation; and
registering the selected memory block as an erase-fail block and terminating the erase operation when a result of the second erase verify operation is determined as fail.

17. A method of operating a memory device, the method comprising:
sequentially performing a soft erase operation and a pre-program operation on a selected memory block including programmed memory cells;
performing a first main erase operation after the pre-program operation; and
performing an erase verify operation to determine an erase pass or an erase fail of the selected memory block.

18. The method of claim 17, further comprising, before performing the soft erase operation:
measuring an internal temperature; and
setting operating voltages for the soft erase operation and the pre-program operation based on a measured internal temperature or a program/erase cycle count of the selected memory block.

19. The method of claim 17, further comprising sequentially performing a second main erase operation and a second verify erase operation on the selected memory block when a result of the erase verify operation is determined as erase fail.

20. The method of claim 19, wherein when a result of the second erase verify operation is determined as fail, the selected memory block is registered as an erase-fail block and an erase operation is terminated.
